(19) United States
(12) Patent Application Publication
(10) Pub. No.: US 2009/0199887 A1
(43) Pub. Date: Aug. 13, 2009

(54) METHODS OF FORMING THERMOELECTRIC DEVICES INCLUDING EPITAXIAL THERMOELECTRIC ELEMENTS OF DIFFERENT CONDUCTIVITY TYPES ON A SAME SUBSTRATE AND RELATED STRUCTURES

(75) Inventors: Mark Johnson, Raleigh, NC (US); Lauren Jackson, Wilkesboro, NC (US); Robert Vaudo, Cary, NC (US); James Mundell, Raleigh, NC (US)

Correspondence Address: MYERS BIGEL SIBLEY & SAJOVEC, PO BOX 37428, RALEIGH, NC, 27627, US

(73) Assignee: North Carolina State University and Nextreme Thermal Solutions, Inc.

(21) Appl. No.: 12/367,043

(22) Filed: Feb. 6, 2009

Related U.S. Application Data
(60) Provisional application No. 61/065,067, filed on Feb. 8, 2008.

(51) Int. Cl. H01L 35/14; H01L 21/20; H01L 21/02

(52) U.S. Cl. 136/239; 438/54; 438/681; 257/E21.09; 257/E21.002

(57) ABSTRACT

A method of forming a thermoelectric device may include forming a first pattern of epitaxial thermoelectric elements of a first conductivity type on a surface of a semiconductor substrate. A second pattern of epitaxial thermoelectric elements of a second conductivity type may be formed on the surface of the semiconductor substrate. Moreover, the thermoelectric elements of the first and second patterns may be spaced apart, and the first and second conductivity types may be different. Related structures are also discussed.

### RELATED APPLICATION

The present application claims the benefit of priority from U.S. Provisional Application Ser. No. 61/065,067 filed Feb. 8, 2008, the disclosure of which is hereby incorporated herein in its entirety by reference.

### FIELD OF THE INVENTION

The present invention relates to the field of electronics, and more particularly, to thermoelectric methods and structures.

### BACKGROUND

Thermoelectric materials such as p-BiₓSb₂₋ₓTe₃ and n-Bi₂Te₃₋ₓSeₓ may be used to provide heat pumping (e.g., cooling and/or heating) and/or power generation according to the Peltier effect. Thermoelectric materials and structures are discussed, for example, in the reference by Venkatasubramanian et al. entitled “Phonon-Blocking Electron-Transmitting Structures” (18^{th} International Conference On Thermoelectrics, 1999), the disclosure of which is hereby incorporated herein in its entirety by reference.

A thermoelectric device, for example, may include one or more thermoelectric pairs with each thermoelectric pair including a p-type thermoelectric element and an n-type thermoelectric element that are electrically coupled in series and that are thermally coupled in parallel, and each of the thermoelectric elements of a pair may be formed of a thermoelectric material such as bismuth telluride (p-type or n-type Bi₂Te₃). Conventionally, the p-type and n-type thermoelectric elements may be formed separately and then mechanically assembled into a thermoelectric device. Fabrication and assembly of separate p-type and n-type thermoelectric elements, however, may dictate a minimum feature size and element density that may be obtainable, thereby reducing efficiency gains that may otherwise be available with further reductions in feature sizes.

### SUMMARY

According to some embodiments of the present invention, a method of forming a thermoelectric device may include forming a first pattern of epitaxial thermoelectric elements of a first conductivity type on a surface of a semiconductor substrate. A second pattern of epitaxial thermoelectric elements of a second conductivity type may be formed on the surface of the semiconductor substrate. Moreover, the thermoelectric elements of the first and second patterns may be spaced apart, and the first and second conductivity types may be different.

Forming the first pattern of epitaxial thermoelectric elements may include forming a first mask on the semiconductor substrate defining a first pattern of exposed regions of the semiconductor substrate. A layer of a first epitaxial thermoelectric material of the first conductivity type may be formed on the first pattern of exposed regions of the semiconductor substrate. The first pattern of epitaxial thermoelectric elements may then be provided by removing the first mask while maintaining the first epitaxial material on the first pattern of exposed regions of the semiconductor substrate.

Forming the second pattern of epitaxial thermoelectric elements may include forming a second mask on the semiconductor substrate and on the first pattern of epitaxial thermoelectric elements after removing the first mask, with the second mask defining a second pattern of exposed regions of the semiconductor substrate. A layer of a second epitaxial thermoelectric material of the second conductivity type may be formed on the second pattern of exposed regions of the semiconductor substrate. The second pattern of epitaxial thermoelectric elements may then be provided by removing the second mask while maintaining the second epitaxial material on the second pattern of exposed regions of the semiconductor substrate.

The first and/or second mask may include silicon nitride and/or silicon oxide. Moreover, the first and/or second epitaxial thermoelectric material may be formed using metal organic chemical vapor deposition (MOCVD), and the epitaxial thermoelectric elements may be bismuth telluride thermoelectric elements. The substrate may include a gallium arsenide substrate.

In addition, at least one of a diode, a transistor, and/or a sensor may be formed on the semiconductor substrate. The at least one of a diode, a transistor, and/or a sensor, for example, may be formed on the same surface of the semiconductor substrate on which the epitaxial thermoelectric elements are formed, or the at least one of a diode, a transistor, and/or a sensor may be formed on a second surface of the semiconductor substrate opposite the first surface. The first and second patterns of epitaxial thermoelectric elements may be arranged so that one of the epitaxial thermoelectric elements of the first conductivity type is between two of the epitaxial thermoelectric elements of the second conductivity type and so that one of the epitaxial thermoelectric elements of the second conductivity type is between two of the epitaxial thermoelectric elements of the first conductivity type.

Before forming the first and second patterns of epitaxial thermoelectric elements, a pattern of electrically conductive regions may be formed in the semiconductor substrate. After forming the first and second patterns of epitaxial thermoelectric elements, each electrically conductive region of the semiconductor substrate may provide an electrical coupling between a respective one of the epitaxial thermoelectric elements of the first conductivity type and a respective one of the epitaxial thermoelectric elements of the second conductivity type. Moreover, a heat spreader may be coupled to the first and second patterns of epitaxial thermoelectric elements. The heat spreader may include a pattern of conductive traces with each conductive trace providing an electrical coupling between a respective one of the epitaxial thermoelectric elements of the first conductivity type and a respective one of the epitaxial thermoelectric elements of the second conductivity type so that the epitaxial thermoelectric elements of the first and second patterns are electrically coupled in series and thermally coupled in parallel between the semiconductor substrate and the heat spreader.

According to some other embodiments of the present invention, a thermoelectric structure may include a semiconductor substrate and a first pattern of epitaxial thermoelectric elements of a first conductivity type on a surface of the semiconductor substrate. More particularly, crystal structures of the first pattern of thermoelectric elements may be aligned with a crystal structure of the semiconductor substrate. In addition, a second pattern of epitaxial thermoelectric elements of a second conductivity type may be on the surface of the semiconductor substrate, the thermoelectric elements of the first and second patterns may be spaced apart, and the first and second conductivity types may be different. Moreover, crystal structures of the second pattern of epitaxial thermoelectric elements may be aligned with the crystal structure of the semiconductor substrate. Accordingly, single crystal epitaxial thermoelectric elements of opposite conductivity types (i.e., n-type and p-type) may have crystal structures that are aligned with a crystal structure of a single crystal substrate.

The epitaxial thermoelectric elements may include bismuth telluride thermoelectric elements, and the substrate may be a gallium arsenide substrate. Moreover, at least one of a diode, a transistor, and/or a sensor may be provided in and/or on the semiconductor substrate. The at least one of a diode, a transistor, and/or a sensor and the epitaxial thermoelectric elements may be on the same surface of the semiconductor substrate, or the thermoelectric elements and the at least one of a diode, a transistor, and/or a sensor may be on opposite surfaces of the semiconductor substrate. The first and second patterns of epitaxial thermoelectric elements may be arranged so that one of the epitaxial thermoelectric elements of the first conductivity type is between two of the epitaxial thermoelectric elements of the second conductivity type and so that one of the epitaxial thermoelectric elements of the second conductivity type is between two of the epitaxial thermoelectric elements of the first conductivity type.

In addition, a pattern of electrically conductive regions may be provided in the semiconductor substrate, with each electrically conductive region of the semiconductor substrate providing an electrical coupling between a respective one of the epitaxial thermoelectric elements of the first conductivity type and a respective one of the epitaxial thermoelectric elements of the second conductivity type. A heat spreader may be coupled to the first and second patterns of epitaxial thermoelectric elements, and the heat spreader may include a pattern of conductive traces with each conductive trace providing an electrical coupling between a respective one of the epitaxial thermoelectric elements of the first conductivity type and a respective one of the epitaxial thermoelectric elements of the second conductivity type. The epitaxial thermoelectric elements of the first and second patterns may thus be electrically coupled in series and thermally coupled in parallel between the semiconductor substrate and the heat spreader.

### BRIEF DESCRIPTION OF THE DRAWINGS

FIGS. 1A to 1F are cross sectional views illustrating operations of forming n-type and p-type thermoelectric elements on a same substrate according to some embodiments of the present invention.

FIG. 2 is a plan view corresponding to the cross sectional view of FIG. 1F illustrating an array of epitaxial thermoelectric elements according to some embodiments of the present invention.

FIG. 3 is a cross sectional view illustrating a heat spreader bonded to thermoelectric elements of FIGS. 1F and 2 according to some embodiments of the present invention.

FIGS. 4 and 5 are cross sectional views illustrating a semiconductor substrate having both a heat generating device and epitaxial thermoelectric elements formed thereon according to some embodiments of the present invention.

FIGS. 6-9 are cross sectional views illustrating examples of heat generating devices formed on a semiconductor substrate according to some embodiments of the present invention.

### DETAILED DESCRIPTION

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or-groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. Accordingly, these terms can include equivalent terms that are created after such time. It will be farther understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein. All publications, patent applications, patents, and other references mentioned herein are incorporated by reference in their entirety.

According to some embodiments of the present invention, sequential selected area epitaxy of Bismuth Telluride (or other thermoelectric materials) may be used to form thermoelectric elements of different conductivity types directly on a same semiconductor substrate (e.g., a gallium arsenide or GaAs semiconductor substrate). For example, sequential selected area epitaxy may be used to form thermoelectric elements of different conductivity types for a thermoelectric cooling device directly on a semiconductor substrate of an electronic device such as a diode (e.g., a laser diode, a light emitting diode, a photodiode, etc.), a transistor (e.g., a bipolar transistor, a field effect transistor, etc.), and/or a sensor (e.g., a biosensor), using direct heterogeneous integration. A thermoelectric cooling device may thus be integrated with such an electronic device (e.g., a diode, a transistor, and/or a sensor) on a same semiconductor substrate (either before or after forming the electronic device) to provide integrated junction level device cooling. This thermoelectric cooling may enable higher power or more stable power operation of electronic devices such as semiconductor laser diodes. Efficiency of a semiconductor laser diode, for example, may be improved by integrating thermoelectric cooling directly with the semiconductor laser (at a junction level), as opposed to mechanically assembling a thermoelectric device separate from the laser diode and then attaching the thermoelectric device to the laser (at the die level).

Selected area epitaxy may be used to effectively deposit epitaxial thermoelectric materials on a semiconductor substrate of a dissimilar semiconductor material in a controlled and spatially directed manner. Examples of selected area epitaxy include the selected area lateral epitaxy of gallium nitride (GaN) as used in blue laser diode fabrication, and the regrown source-drain contact growth of silicon germanium (Si—Ge) in mobility enhanced uniaxially strained silicon nanoelectronics. Thermoelectric materials such as n-type and p-type Bismuth Telluride (Bi₂Te₃) may be deposited using metal-organic chemical vapor deposition (MOCVD) on Gallium Arsenide (GaAs) as a broad area process (i.e., deposited on an entire wafer) and subsequently diced into sections for assembly into thermoelectric diode devices. The resulting thermoelectric diodes may provide thermoelectric devices with characteristic size-scales on the order of millimeters.

Using selected area epitaxy, a Gallium Arsenide semiconductor wafer may be patterned using photolithography with spatial areas on a size scale on the order of tens of microns or less. Using selected area epitaxy, sequential patterning to deposit n-type and p-type Bismuth Telluride material on the same Gallium Arsenide substrate may provide direct heterogeneous integration of thermoelectric devices. Accordingly, thermoelectric devices/structures may be formed using known semiconductor processing tools to provide a GaAs device with a heterogeneously integrated thermoelectric cooling device. According to some embodiments of the present invention, an individual high power laser diode (e.g., a 980 nm pump laser) and/or a high power laser array may be integrated with a thermoelectric cooling device on a same GaAs semiconductor substrate. A linear structure of a laser stripe may facilitate integration with a thermoelectric cooling device as a front-side or back-side process. Selected area epitaxy of Bismuth Telluride on a GaAs semiconductor substrate may thus be provided using MOCVD to form n-type and p-type thermoelectric elements on a same substrate thereby reducing mechanical assembly operations used to form a thermoelectric cooling device.

Heterogeneous integration according to embodiments of the present invention may enable new products which combine thermoelectric and photonic (or electronic) functionality at a junction level. Such integrated products may provide improved performance capability (e.g., reduced peak power consumption, increased reliability, increased stability, increased efficiency, increased linearity, etc.) relative to existing products. In markets for high power lasers and/or photonics, such improved performance may translate as market competitive advantages.

According to some embodiments of the present invention, thermoelectric crystal materials may be deposited directly on a semiconductor substrate to provide thermoelectric cooling structures for semiconductor devices such as semiconductor photonic devices, semiconductor electronic devices, and/or semiconductor bio-electronic devices. Thermoelectric materials have a property such that when two thermoelectric elements of different conductivity types are connected in an appropriate geometry (‘a thermoelectric device’), passing of an electric current through the device may force cooling by the flow (or pumping) of heat from one location to another. Thermoelectric devices have been proposed to cool semiconductor laser devices to allow higher optical powers and/or stability. High power photonic devices (e.g., pump laser diodes and/or laser diode arrays) may need to be cooled to remove excess, deleterious heat which may result during operation. Otherwise, a build-up of heat may limit power, reliability, and/or stability of such lasers.

Effective combinations of two or more thermoelectric materials of different conductivity types into thermoelectric devices has presented challenges. For example, n-type and p-type thermoelectric materials may be separately formed on separate substrates, diced into n-type and p-type thermoelectric elements, and then mechanically assembled (e.g., using pick and place and solder techniques) into thermoelectric devices. Mechanical assembly, however, may be limited relative to size and cost scaling, cost-performance trade-offs, reliability, and/or efficiency in thermoelectric cooling of lasers. By depositing n-type and p-type thermoelectric semiconductor materials (e.g., n-type and p-type Bismuth Telluride) sequentially (e.g., using selected area epitaxial MOCVD deposition) on a laser substrate (e.g., a GaAs substrate), mechanical assembly challenges may be reduced.

Thermal dissipation may be a challenge for semiconductor devices such as photonic, electronic, and/or bio-electronic semiconductor devices, and technologies that address thermal dissipation of heat generated in a semiconductor device may be of financial value. The physically closer a thermoelectric cooling device-is located to the source of heat (e.g., the junction) in the semiconductor device, the greater the effectiveness may be at providing cooling. When a thermoelectric cooling device is assembled to the backside of a laser die (at the die level), the thermoelectric cooling device may be required to pump heat from the frontside of the laser die, through the substrate to the backside of the laser die. According to embodiments of the present invention using sequential selective area epitaxy to form n-type and p-type thermoelectric elements directly on the frontside of a laser die (so that the thermoelectric elements and the laser are formed on a same surface of the laser die substrate), thermoelectric cooling may be integrated with the laser substrate (adjacent to the junction level). Using direct heterogeneous integration according to some embodiments of the present invention, a thermoelectric cooling device may be located adjacent to the laser junction to thereby improve cooling.

Combination of semiconductor materials with different functionalities may provide a manufacturing processes to combine integrated device functions. For example, an optical function of a photonic device may be combined with the thermal function of a thermoelectric cooling device and/or with the electrical function of a control transistor device on a same semiconductor substrate. This combination of platform functionalities may enable potentially new device or system level capabilities.

Direct heterogeneous integration of thermoelectric devices (using sequential selective area epitaxial deposition) may enable a more manufactureable process with reduced mechanical assembly and improved cost-performance tradeoffs. Moreover, selected area patterning and epitaxial growth according to embodiments of the present invention may use standard semiconductor fabrication equipment.

According to some embodiments of the present invention, sequential selected area epitaxy of n-type and p-type Bismuth Telluride thermoelectric elements on a Gallium Arsenide substrate may be used to provide direct heterogeneous integration of thermoelectric cooling for laser diode and related semiconductor applications. More particularly, n-type thermoelectric elements and p-type thermoelectric elements may be sequentially formed on a semiconductor device substrate using epitaxial MOCVD depositions and using different selected area deposition masks. The n-type and p-type thermoelectric elements may thus be formed directly on a device substrate (e.g., a laser diode substrate) at the wafer level before dicing. By way of example, selected area epitaxial deposition may be used according to embodiments of the present invention to form n-type and p-type thermoelectric elements directly on semiconductor substrates including photonic laser diodes (e.g., for optical pumps), photonic laser diode arrays (e.g., for sensors and/or systems), photonic high brightness light emitting diodes (e.g., for illumination), photonic avalanche photodiode arrays (e.g., for sensing), photonic diode sensor arrays (e.g., for imaging), electronic heterojunction bipolar junction transistors (e.g., for linear broadband communications amplifiers), electronic high electron mobility transistors (e.g., for linear broadband communications amplifiers), electronic heterojunction field effect transistors (e.g., for high power linear amplifiers), integrated semiconductor wafers (e.g., as materials for photonic, electronic, and/or biotechnology applications), nanoscale CMOS electronics (e.g., for high density digital integrated circuit devices), and/or cooled semiconductor microfluidics devices (e.g., for biosensor and/or bio-assay instrumentation in biotechnology). By way of further example, n-type and p-type thermoelectric elements may be formed directly on an active surface of a semiconductor substrate for a high power stripe laser diode.

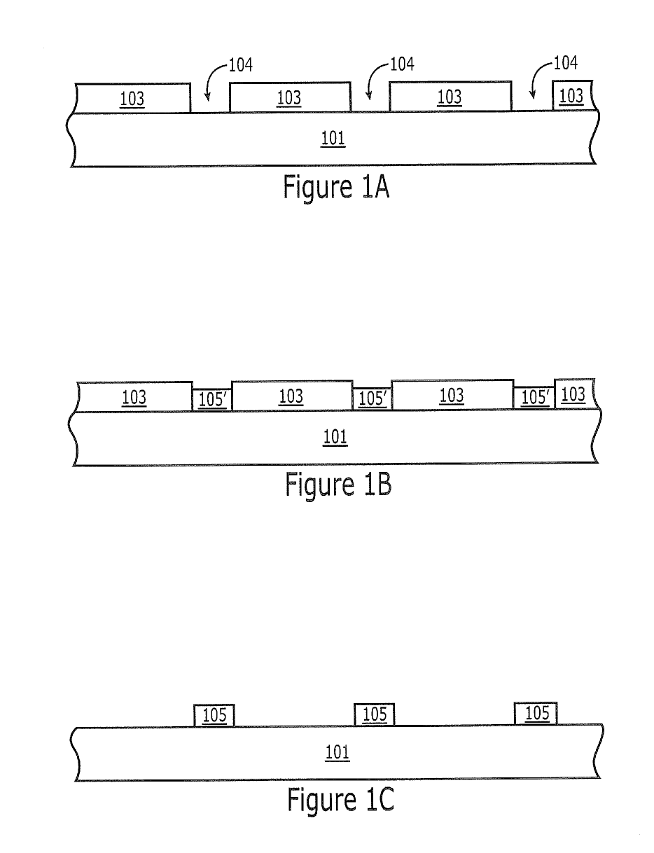

FIGS. 1A to 1F are cross sectional views illustrating operations of forming epitaxial n-type and p-type thermoelectric elements on a same substrate according to some embodiments of the present invention. A portion of a substantially single crystal semiconductor substrate 101, such as a GaAs semiconductor substrate, may be provided for forming a thermoelectric device according to some embodiments of the present invention. While GaAs substrates are discussed by way of example, silicon or any other epitaxially suitable single crystal substrate may be used. As shown in FIG. 1A, a first mask 103 may be formed on the semiconductor substrate, and the first mask may include openings defining a first pattern of exposed regions 104 of the semiconductor substrate 101. The first mask 103, for example, may include a mask material such as silicon nitride (SiN) and/or silicon oxide (SiO₂), and the first mask 103 may be formed using a blanket deposition (e.g., plasma enhanced chemical vapor deposition or PECVD) of a mask material on the semiconductor substrate 101 followed by photolithographic patterning of the mask material.

After forming the first mask 103, a layer/layers 105′ of a first epitaxial thermoelectric material (such as Bismuth Telluride) of a first conductivity type may be formed on the first pattern of exposed regions of the semiconductor substrate using selective area epitaxial deposition as shown in FIG. 1B. More particularly, the layer/layers 105′ of the first thermoelectric material may be formed using metal organic chemical vapor deposition (MOCVD). While MOCVD is discussed by way of example, other deposition techniques (such as evaporation, sputtering, and/or molecular beam epitaxy) may be used. After forming the layer/layers 105′ of the first thermoelectric material, the first mask 103 may be removed so that a first pattern of thermoelectric elements 105 of the first conductivity type remains on the semiconductor substrate as shown in FIG. 1C.

By using selective area epitaxial deposition to form the first layer/layers 105′ of thermoelectric material of the first conductivity type, substantial deposition may only occur on portions of the semiconductor substrate 101 exposed through openings of the first mask 103. Moreover, the resulting thermoelectric elements 105 may have an epitaxial crystal structure such that a crystal structure of the thermoelectric elements 105 is matched with a crystal structure of the single crystal semiconductor substrate 101.

As shown in FIG. 1B, the layer/layers 105′ of the first thermoelectric material of the first conductivity type (e.g., n-type) may be confined within openings though the first mask 103. According to other embodiments of the present invention, the layer/layers 105′ may extend outside these openings onto a surface of the first mask 103 opposite the substrate 101. If overgrowth occurs, polishing and/or etch back operations may be performed before removing the first mask 103, and/or excess portions of the layer/layers 105′ outside the openings may be removed when the first mask 103 is removed.

As shown in FIG. 1D, a second mask 107 may be formed on the semiconductor substrate 101 and on the thermoelectric elements 105 of the first conductivity type, and the second mask 107 may define a second pattern of exposed regions 108 of the semiconductor substrate 101. The second mask 107, for example, may include a mask material such as silicon nitride (SiN) and/or silicon oxide (SiO₂), and the second mask 107 may be formed using a blanket deposition (e.g., plasma enhanced chemical vapor deposition or PECVD) of a mask material followed by photolithographic patterning of the mask material.

After forming the second mask 107, a layer/layers 109′ of a second epitaxial thermoelectric material (such as Bismuth Telluride) of a second conductivity type (e.g., p-type) may be formed on the second pattern of exposed regions of the semiconductor substrate using selective area epitaxial deposition, as shown in FIG. 1E. More particularly, the layer/layers 109′ of the second thermoelectric material may be formed using metal organic chemical vapor deposition (MOCVD). While MOCVD is discussed by way of example, other deposition techniques (such as evaporation, sputtering, and/or molecular beam epitaxy) may be used. After forming the layer/layers 109′ of the second thermoelectric material, the second mask 107 may be removed so that a second pattern of thermoelectric elements 109 of the second conductivity type remains on the semiconductor substrate (together with the first pattern of thermoelectric elements 105 of the first conductivity type) as shown in FIG. 1F.

By using selective area epitaxial deposition to form the second layer/layers 109′ of thermoelectric material of the second conductivity type, substantial deposition may only occur on portions of the semiconductor substrate 101 exposed through openings of the second mask 107. Moreover, the resulting thermoelectric elements 109 may have an epitaxial crystal structure such that a crystal structure of the thermoelectric elements 109 is matched with a crystal structure of the single crystal semiconductor substrate 101.

As shown in FIG. 1E, the layer/layers 109′ of the second thermoelectric material of the second conductivity type may be confined within openings though the second mask 107. According to other embodiments of the present invention, the layer/layers 109′ may extend outside these openings onto a surface of the second mask 107 opposite the substrate 101. If overgrowth occurs, polishing and/or etch back operations may be performed before removing the second mask 107, and/or excess portions of the layer/layers 109′ outside the openings may be removed when the second mask 107 is removed.

The thermoelectric elements 105 may have a first conductivity type and the thermoelectric elements 109 may have a second conductivity type different than the first conductivity type. According to some embodiment of the present invention, the thermoelectric elements 105 may have n-type conductivity and the thermoelectric elements 109 may have p-type conductivity so that the n-type conductivity thermoelectric elements are formed first. According to other embodiments of the present invention, the thermoelectric elements 105 may have p-type conductivity and the thermoelectric elements 109 may have n-type conductivity so that the p-type conductivity thermoelectric elements are formed first. According to some embodiments of the present invention, each of the n-type and p-type epitaxial thermoelectric elements may be formed from a single crystal semiconductor material including Bi and Te. For example, p-type thermoelectric elements may be provided using single crystal BiSbTe, and n-type thermoelectric elements may be provided using single crystal BiTe and/or BiTeSe.

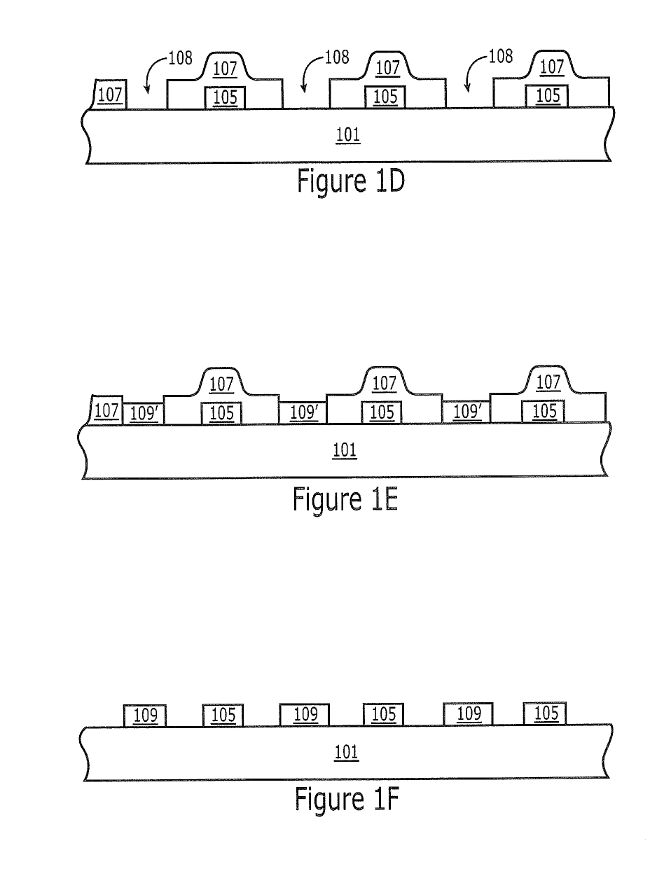

FIG. 2 is a plan view (corresponding to the cross sectional view of FIG. 1F) illustrating an array of epitaxial thermoelectric elements 105 and 109 that may be formed on a same semiconductor substrate 101 as discussed above with respect to FIGS. 1A to 1F. The thermoelectric elements 105 and 109 may be alternatingly arranged in rows and columns so that a thermoelectric element 105 of the first conductivity type is between two thermoelectric elements 109 of the second conductivity type, and so that a thermoelectric element 109 of the second conductivity type is between two thermoelectric elements 105 of the first conductivity type. A six by six array of thermoelectric elements 105 and 109 is shown in FIG. 2 by way of example, but other arrangements may be provided according to other embodiments of the present invention. Because dimensions of the thermoelectric elements 105 and 109 are determined by photolithographic patterning of the mask layers 103 and 107, dimensions (e.g., lengths, widths, and/or diameters) of the thermoelectric elements 105 and 109 (and spaces therebetween) may be provided in the range of about 10 microns to about 100 microns.

According to other embodiments of the present invention, the structure of FIGS. 1F and 2 may be formed using one or more blanket epitaxial deposition and photolithographic patterning operations. For example, the structure of FIG. 1C may be provided by forming a blanket layer of the first thermoelectric material (by epitaxial deposition) across an entirety of the substrate 101, and then patterning the blanket layer of the first thermoelectric material (using photolithography and etch operations) to form the first pattern of thermoelectric elements 105 as shown in FIG. 1C. By using an etchant that does not significantly damage exposed portions of the substrate 101 between thermoelectric elements 105, a subsequent epitaxial deposition for the other thermoelectric elements (i.e., thermoelectric elements 109) may be performed. The second pattern of thermoelectric elements 109 may then be formed as discussed above with respect to FIGS. 1D, 1E, and 1F.

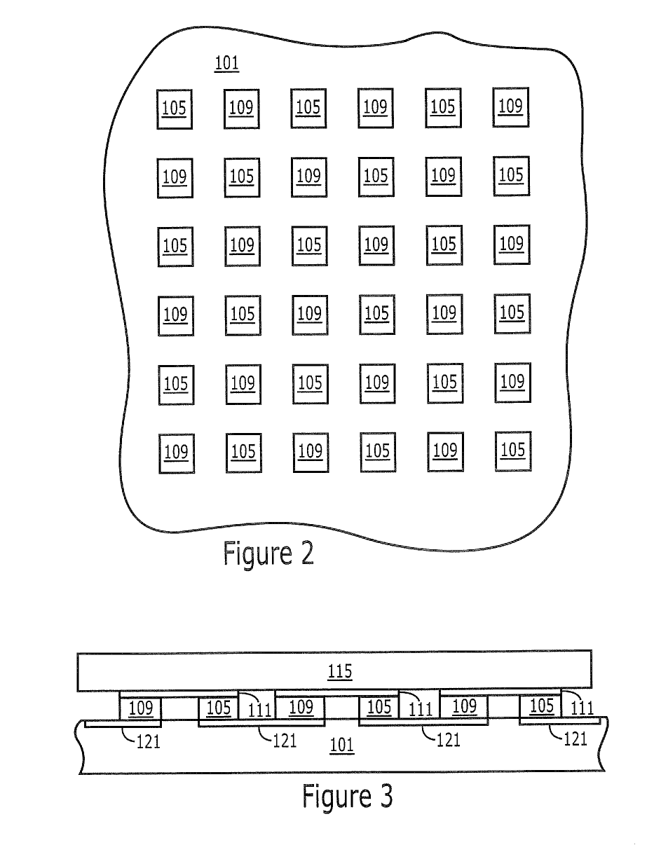

As shown in FIG. 3, a heat spreader 115 including electrically conductive traces 111 (e.g., copper traces) thereon may be bonded to the thermoelectric elements 105 and 109. The heat spreader 115 may include a thermally conductive and electrically insulating material (such as aluminum nitride), or the heat spreader 115 may include a thermally and electrically conductive material (such as copper) with a thin electrically insulating layer (such as silicon oxide and/or silicon nitride) thereon to provide electrical isolation for the electrically conductive traces 111. The electrically conductive traces 111 may be photolithographically patterned on the heat spreader 115 before bonding with the thermoelectric elements 105 and 109. The heat spreader 115 may be bonded with the thermoelectric elements 105 and 109, for example, using solder bonds between the electrically conductive traces 111 and the thermoelectric elements 105 and 109. Each pair of thermoelectric elements 105 and 109 of opposite conductivity type that are coupled to a same electrically conductive trace 111 may thus define a P—N couple so that the thermoelectric elements of a P—N couple are electrically coupled in series and thermally coupled in parallel between the semiconductor substrate 111 and the heat spreader 115. As used herein, the term heat spreader includes any structure configured to conduct heat to/from thermoelectric elements 105 and 109. The heat spreader 115, for example, may be a portion of and/or may be thermally coupled to a heat sink, a heat pipe, a heat dissipating fin structure, etc.

According to some embodiments of the present invention, conductive regions 121 of the semiconductor substrate 101 may provide electrical couplings between adjacent P—N couples as shown in FIG. 3. Conductive regions 121, for example, may be formed by selectively doping regions 121 of semiconductor substrate 101 before forming the first mask 103. By maintaining a crystal structure of the substrate 101 in these conductive regions 121, thermoelectric elements 105 and 109 may be epitaxially formed thereon. According to other embodiments of the present invention, conductive regions 121 may be metal traces formed on substrate 101 before forming thermoelectric elements 105 and 109 thereon. According to still other embodiments of the present invention, lateral heat pumping (i.e., heat pumping in a direction parallel with a surface of substrate 101) may be provided through the thermoelectric elements using planar structures such as those discussed, for example, by Hwang et al., in “Micro Thermoelectric Cooler: Planar Multistage”, Int.J.Heat Mass Transfer (2008), and by Goncalves et al., in “On-Chip array of Thermoelectric Peltier Microcoolers”, Sensors and Actuators A, 145-146 (2008), pages 75-80. With lateral heat pumping electrical current is provided through thermoelectric elements 105/109 in a direction parallel with respect to substrate 101 (into or out of the page of FIG. 3) so that so that conductive traces may be deposited on opposite sidewalls of thermoelectric elements 105/109 after deposition thereof. All of the electrical interconnections, for example, may be provided on substrate 101 without requiring a heat spreader 115 and without requiring conductive regions 121 between thermoelectric elements 105/109 and substrate 101, or all of the electrical interconnections may be provided on heat spreader 115. The couplings of thermoelectric elements 105 and 109 shown in FIG. 3 and/or other couplings may thus provide thermoelectric heat pumping and/or power generation because the resulting current path through the thermoelectric elements 105 and 109 provides opposite directions of current flow through thermoelectric elements of opposite conductivity types.

According to yet other embodiments of the present invention, epitaxial thermoelectric elements 105 and 109 of different conductivity types may be formed on single crystal substrate 101 as shown in FIGS. 1F and 2, and the single crystal substrate 101 may be a sacrificial substrate. Once the epitaxial thermoelectric elements 105 and 109 are formed on the substrate, the thermoelectric elements 105 and 109 may be bonded with electrically conductive traces 111 on heat spreader 115 as shown in FIG. 3. After bonding with traces 111, the substrate 101 may be removed, for example, by etching so that growth surfaces of the thermoelectric elements 105 and 109 are exposed. A second heat spreader and/or other structure including appropriate conductive paths/traces may then be bonded to the exposed growth surfaces of the thermoelectric elements 105 and 109. The resulting structure may be similar to that illustrated in FIG. 3 with the second heat spreader substituted for substrate 101 and with conductive traces substituted for conductive regions. By using a same growth substrate 101, thermoelectric elements 105 and l 09 may be more easily aligned with heat spreader 115 is a single alignment/bonding operation. By removing the growth substrate 101 and using a different second heat spreader, an epitaxial growth of thermoelectric elements 105 and 109 may be facilitated because conductive regions 121 are not present on the growth substrate 101 during epitaxial growth.

As shown in FIGS. 1F, 2, and 3, each thermoelectric element 105 of the first conductivity type may be paired with a respective thermoelectric element 109 of the second conductivity type. As shown in FIG. 2, a checker board pattern may be provided with each row including alternating thermoelectric elements of different conductivity types, and with each column including alternating thermoelectric elements of different conductivity types. According to other embodiments of the present invention, other arrangements may be provided so long as electrical contact is provided for pairs of thermoelectric elements of different conductivity types. For example, each row may include thermoelectric elements of only one conductivity type with adjacent rows having thermoelectric elements of different conductivity types.

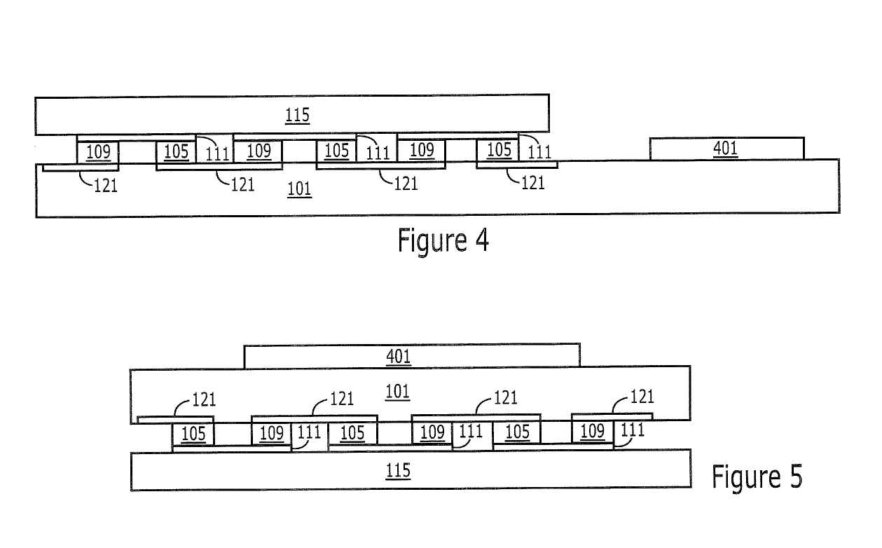

Operations and structures discussed above with respect to FIGS. 1A to 1F, FIG. 2, and FIG. 3 may be used to form p-type and n-type thermoelectric elements 105 and 109 directly on a semiconductor substrate 101 including a heat generating device (e.g., a diode, transistor, and/or sensor) formed thereon. According to some embodiments of the present invention shown in FIG. 4, the thermoelectric elements 105 and 109 may be formed on the frontside or active side of the substrate 101 so that the heat generating device 401 (e.g., a diode, transistor, and/or sensor) and the thermoelectric elements 105 and 109 are on the same surface of the semiconductor substrate 101. According to other embodiments of the present invention shown in FIG. 5, the thermoelectric elements 105 and 109 may be formed on the backside or inactive side of the substrate 101 so that heat generating device 401 (e.g., a diode, transistor, and/or sensor) and the thermoelectric elements 105 and 109 are on opposite surfaces of the semiconductor substrate 101.

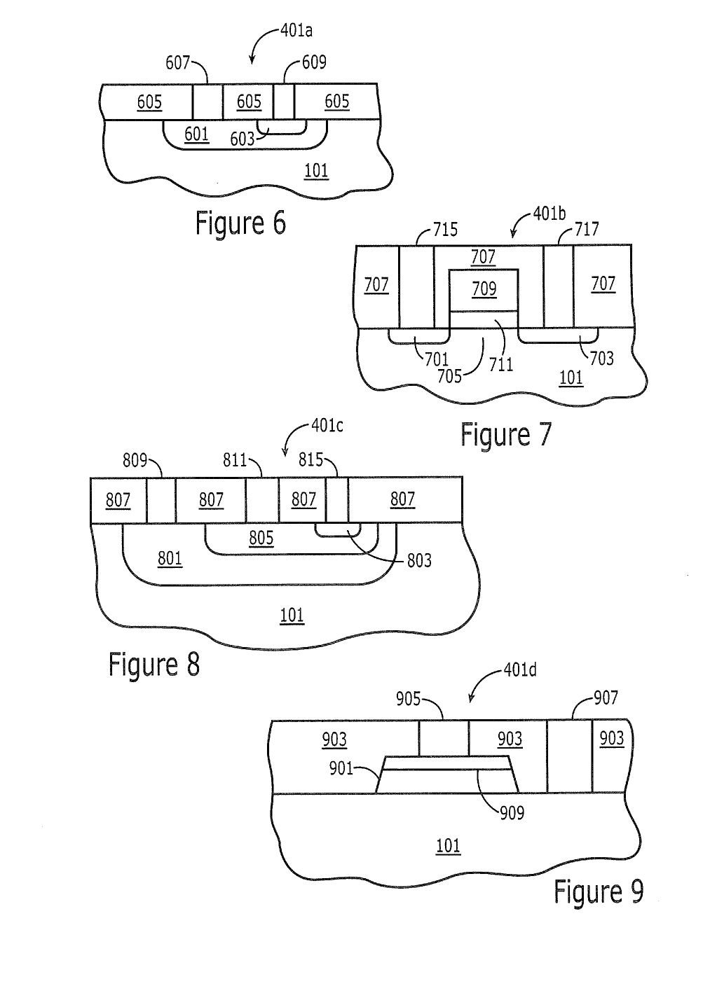

In FIGS. 4 and 5, the heat generating device 401 is shown generically for ease of illustration. In both FIGS. 4 and 5, the heat generating device 401 (e.g., a diode, a transistor, and/or a sensor) may be formed using microfabrication techniques such as thin film deposition, dopant implantation/diffusion, photolithographic patterning, etc. Accordingly, elements of the heat generating device 401 may be formed from portions of the single crystal semiconductor substrate 101 on which the epitaxial thermoelectric elements 105 and 109 are formed. FIGS. 6-9 are cross sectional views illustrating examples of heat generating device 401 of FIGS. 4 and 5.

By way of example, a p-type region 601, an n-type region 603, and/or a junction therebetween of a diode 401 a (such as a laser diode, a light emitting diode, etc.) may be provided using regions of single crystal semiconductor substrate 101 of the appropriate conductivity type(s) as shown in FIG. 6. FIG. 6 also shows insulating layer 605 (e.g., a silicon oxide and/or silicon nitride insulating layer) and electrodes 607 and 609 (e.g., metal electrodes).

Similarly, a source region 701, a drain region 703, and/or a channel region 705 of a field effect transistor 401b may be provided using regions of single crystal semiconductor substrate 101 of the appropriate conductivity type(s) as shown in FIG. 7. FIG. 7 also shows insulating layer 707 (e.g., a silicon oxide and/or silicon nitride layer), gate electrode 709 (e.g., a metal and/or polysilicon gate electrode), gate insulating layer 711 (e.g., a silicon oxide layer), and source/drain electrodes 715 and 717 (e.g., metal electrodes).

With a bipolar transistor 401c, a collector 801, an emitter 803, and/or a base 805 may be provided using regions of single crystal semiconductor substrate 101 of the appropriate conductivity types as shown in FIG. 8. FIG. 8 also shows insulating layer 807 (e.g., a silicon oxide and/or silicon nitride layer), and electrodes 809, 811, and 815 (e.g., metal electrodes).

With a stripe type laser diode 401d, an epitaxial single crystal semiconductor stripe 901 (with p-type and/or n-type diode regions therein) may be formed on single crystal substrate 101 (for example, by epitaxial growth and/or selective etching) as shown in FIG. 9. FIG. 9 also shows insulating layer 903 (e.g., a silicon oxide and/or silicon nitride layer) and electrodes 905 and 907 (e.g., metal electrodes). In addition, a P—N junction 909 may be provided in epitaxial semiconductor stripe 901 between p-type and n-type semiconductor regions. In an alternative, the junction may be provided in the substrate 101 outside the stripe 901.

Accordingly, semiconductor elements/structures (e.g., p-type/n-type diode regions, source/drain/channel field effect transistor regions, collector/emitter/base bipolar transistor regions, epitaxial stripe regions, etc.) of the heat generating device 401 of FIG. 4 and/or FIG. 5 may have single crystal semiconductor structures that are aligned with a crystal structures of single crystal semiconductor substrate 101 and epitaxial thermoelectric elements 105 and 109. While examples of the heat generating device 401 are provided as discrete devices, the heat generating device 401 may be an integrated circuit device (e.g., a microprocessor) including many different electronic elements (e.g., diodes, resistors, capacitors, inductors, conductive traces, conductive through hole vias, etc.) integrated on single crystal semiconductor substrate 101.

As discussed above, epitaxial thermoelectric elements of opposite conductivity types may be formed directly on a substrate to provide integrated thermoelectric cooling of a heat generating device (such as a diode, transistor, and/or sensor) also formed on the same single crystal semiconductor substrate. Epitaxial thermoelectric elements may be formed on a same substrate according to other embodiments of the present invention to provide a discrete thermoelectric cooler that is later coupled to a substrate including the heat generating device. According to still other embodiments of the present invention, epitaxial thermoelectric elements of different conductivity types may be formed on a same substrate to provide thermoelectric power generation, thermoelectric heating, etc.

By forming both n-type and p-type epitaxial thermoelectric elements on a same single crystal growth substrate, sizes of the thermoelectric elements and spacings therebetween may be reduced because mechanical assembly may not be required and/or mechanical assembly operations may be reduced. For example, an entire array of p-type and n-type thermoelectric elements may be placed and bonded in one operation so that placement and bonding of individual elements is not required. Moreover, selective growth of the thermoelectric elements on limited growth areas may reduce cracking, enable lateral (planar) devices and planar staging.

Thermoelectric devices, structures, assemblies, and methods of fabrication/assembly/deposition/operation thereof are discussed by way of example, in: U.S. Pat.Pub.No. 2002/0174660 entitled “Thin-Film Thermoelectric Cooling And Heating Devices For DNA Genomic And Proteomic Chips, Thermo-Optical Switching Circuits, And IR Tags”; U.S. Pat.Pub.No 2003/0099279 entitled “Phonon-Blocking, Electron-Transmitting Low-Dimensional Structures”; U.S. Pat.Pub.No. 2003/0230332 entitled “Thermoelectric Device Utilizing Double-Sided Peltier Junctions And Method Of Making The Device”; U.S. Pat.Pub.No. 2006/0225773 entitled “Trans-Thermoelectric Device”; U.S. Pat.Pub.No. 2006/0086118 entitled “Thin film thermoelectric devices for hot-spot thermal management in microprocessors and other electronics”. U.S. Pat.Pub.No. 2006/0243317 entitled “Thermoelectric Generators For Solar Conversion And Related Systems And Methods”; U.S. Pat.Pub.No. 2006/0289052 entitled “Methods Of Forming Thermoelectric Devices Including Conductive Posts And/Or Different Solder Materials And Related Methods And Structures; U.S. Pat.Pub.No. 2006/0289050 entitled “Methods Of Forming Thermoelectric Devices Including Electrically Insulating Matrixes Between Conductive Traces And Related Structures”; U.S. Pat.Pub.No. 2007/0089773 entitled “Methods Of Forming Embedded Thermoelectric Coolers With Adjacent Thermally Conductive Fields And Related Structures”; U.S. Pat.Pub.No. 20070028956 entitled “Methods Of Forming Thermoelectric Devices Including Superlattice Structures Of Alternating Layers With Heterogeneous Periods And Related Devices”; U.S. Pat.Pub.No. 2007/0215194 entitled “Methods Of Forming Thermoelectric Devices Using Islands Of Thermoelectric Material And Related Structures”; U.S. Pat.Pub.No. 2008/0185030 entitled “Methods Of Depositing Epitaxial Thermoelectric Films Having Reduced Crack And/Or Surface Defect Densities And Related Devices”; U.S. Pat.Pub.No. 2008/0168775 entitled “Temperature Control Including Integrated Thermoelectric Temperature Sensing And Related Methods And Systems”; U.S. Pat.Pub.No. 2008/0264464 entitled “Temperature Control Including Integrated Thermoelectric Sensing And Heat Pumping Devices And Related Methods And Systems”; and U.S. Pat.Pub.No. 2009/0000652 entitled “Thermoelectric Structures Including Bridging Thermoelectric Elements”. The disclosures of all of the above referenced patent publications are hereby incorporated herein in their entirety by reference.

While the present invention has been particularly shown and described with reference to embodiments thereof, it will be understood by those of ordinary skill in the art that various changes in form and details may be made therein without departing from the spirit and scope of the present invention as defined by the following claims.

That which is claimed is:

1. A method of forming a thermoelectric device, the method comprising:
forming a first pattern of epitaxial thermoelectric elements of a first conductivity type on a surface of a semiconductor substrate; and
forming a second pattern of epitaxial thermoelectric elements of a second conductivity type on the surface of the semiconductor substrate wherein the thermoelectric elements of the first and second patterns are spaced apart and wherein the first and second conductivity types are different.

2. A method according to claim 1 wherein forming the first pattern of epitaxial thermoelectric elements comprises,
forming a first mask on the semiconductor substrate defining a first pattern of exposed regions of the semiconductor substrate,
forming a layer of a first epitaxial thermoelectric material of the first conductivity type on the first pattern of exposed regions of the semiconductor substrate, and
removing the first mask while maintaining the first epitaxial material on the first pattern of exposed regions of the semiconductor substrate to provide the first pattern of epitaxial thermoelectric elements.

3. A method according to claim 2 wherein forming the second pattern of epitaxial thermoelectric elements comprises,
after removing the first mask, forming a second mask on the semiconductor substrate and on the first pattern of epitaxial thermoelectric elements wherein the second mask defines a second pattern of exposed regions of the semiconductor substrate,
forming a layer of a second epitaxial thermoelectric material of the second conductivity type on the second pattern of exposed regions of the semiconductor substrate, and
removing the second mask while maintaining the second epitaxial material on the second pattern of exposed regions of the semiconductor substrate to provide the second pattern of epitaxial thermoelectric elements.

4. A method according to claim 2 wherein the first mask comprises silicon nitride and/or silicon oxide.

5. A method according to claim 2 wherein forming the layer of the first epitaxial thermoelectric material comprises forming the layer of the first epitaxial thermoelectric material using metal organic chemical vapor deposition (MOCVD).

6. A method according to claim 1 wherein the epitaxial thermoelectric elements comprises bismuth telluride thermoelectric elements.

7. A method according to claim 1 wherein the substrate comprises a gallium arsenide substrate.

8. A method according to claim 1 further comprising:
forming at least one of a diode, a transistor, and/or a sensor on the semiconductor substrate.

9. A method according to claim 8 wherein forming the at least one of a diode, a transistor, and/or a sensor comprises forming the at least one of a diode, a transistor, and/or a sensor on the same surface of the semiconductor substrate on which the epitaxial thermoelectric elements are formed.

10. A method according to claim 8 wherein the epitaxial thermoelectric elements are formed on a first surface of the semiconductor substrate and wherein forming the at least one of a diode, a transistor, and/or a sensor comprises forming the at least one of a diode, a transistor, and/or a sensor on a second surface of the semiconductor substrate opposite the first surface.

11. A method according to claim 1 wherein the first and second patterns of epitaxial thermoelectric elements are arranged so that one of the epitaxial thermoelectric elements of the first conductivity type is between two of the epitaxial thermoelectric elements of the second conductivity type and so that one of the epitaxial thermoelectric elements of the second conductivity type is between two of the epitaxial thermoelectric elements of the first conductivity type.

12. A method according to claim 1 further comprising:
coupling a heat spreader to the first and second patterns of epitaxial thermoelectric elements, wherein the heat spreader includes a pattern of conductive traces with each conductive trace providing an electrical coupling between a respective one of the epitaxial thermoelectric elements of the first conductivity type and a respective one of the epitaxial thermoelectric elements of the second conductivity type so that the epitaxial thermoelectric elements of the first and second patterns are electrically coupled in series and thermally coupled in parallel between the semiconductor substrate and the heat spreader.

13. A thermoelectric structure comprising:
a semiconductor substrate;
a first pattern of epitaxial thermoelectric elements of a first conductivity type on a surface of the semiconductor substrate wherein crystal structures of the first pattern of thermoelectric elements are aligned with a crystal structure of the semiconductor substrate; and
a second pattern of epitaxial thermoelectric elements of a second conductivity type on the surface of the semiconductor substrate, wherein the thermoelectric elements of the first and second patterns are spaced apart, wherein the first and second conductivity types are different, and wherein crystal structures of the second pattern of epitaxial thermoelectric elements are aligned with the crystal structure of the semiconductor substrate.

14. A thermoelectric structure according to claim 13 wherein the epitaxial thermoelectric elements comprises bismuth telluride thermoelectric elements.

15. A thermoelectric structure according to claim 13 wherein the substrate comprises a gallium arsenide substrate.

16. A thermoelectric structure according to claim 13 further comprising:
at least one of a diode, a transistor, and/or a sensor in and/or on the semiconductor substrate.

17. A thermoelectric structure according to claim 16 wherein the at least one of a diode, a transistor, and/or a sensor and the epitaxial thermoelectric elements are on the same surface of the semiconductor substrate.

18. A thermoelectric structure according to claim 16 wherein the thermoelectric elements are on a first surface of the semiconductor substrate and wherein the at least one of a diode, a transistor, and/or a sensor are on a second surface of the semiconductor substrate opposite the first surface.

19. A thermoelectric structure according to claim 13 wherein the first and second patterns of epitaxial thermoelectric elements are arranged so that one of the epitaxial thermoelectric elements of the first conductivity type is between two of the epitaxial thermoelectric elements of the second conductivity type and so that one of the epitaxial thermoelectric elements of the second conductivity type is between two of the epitaxial thermoelectric elements of the first conductivity type.

20. A thermoelectric structure according to claim 19 further comprising:
a heat spreader coupled to the first and second patterns of epitaxial thermoelectric elements, wherein the heat spreader includes a pattern of conductive traces with each conductive trace providing an electrical coupling between a respective one of the epitaxial thermoelectric elements of the first conductivity type and a respective one of the epitaxial thermoelectric elements of the second conductivity type so that the epitaxial thermoelectric elements of the first and second patterns are electrically coupled in series and thermally coupled in parallel between the semiconductor substrate and the heat spreader.
